(19) United States
(12) Patent Application Publication
(10) Pub. No.: US 2019/0296267 A1
(43) Pub. Date: Sep. 26, 2019

(54) Light-Emitting Component and Method for Producing a Light-Emitting Component

(71) Applicant: OSRAM OLED GmbH, Regensburg (DE)

(72) Inventor: Arne Fleißner, Regensburg (DE)

(21) Appl. No.: 15/571,794

(22) PCT Filed: May 3, 2016
(86) PCT No.: PCT/EP2016/059840

§ 371 Date: Jun. 13, 2019

(30) Foreign Application Priority Data
May 5, 2015 (DE) 102015106942.3

(51) Int. Cl. H01L 51/56; H01L 51/00; G09G 3/3233

(52) U.S. Cl. CPC H01L 51/56; G09G 2320/043; G09G 3/3233; H01L 51/0015

(57) ABSTRACT

A light-emitting component and a method for producing a light-emitting component are disclosed. I an embodiment the light-emitting component includes a layer sequence for generating light, wherein the layer sequence comprises a marking, and wherein the marking is formed as a luminescence degradation of the layer sequence.

This patent application is a national phase filing under section 371 of PCT/EP2016/059840, filed May 3, 2016, which claims the priority of German patent application 10 2015 106 942.3, filed May 5, 2015, each of which is incorporated herein by reference in its entirety.

### TECHNICAL FIELD

A light-emitting component having a marking as well as a method for producing the light-emitting component are provided.

### SUMMARY OF THE INVENTION

Embodiments provide a method for producing a light-emitting component having a marking, which contributes to the traceability as well as to an enhanced counterfeit protection of the light-emitting component.

According to a first aspect, a light-emitting component having a layer sequence for generating light is provided, which has a marking. The light-emitting component can be a light-emitting diode, in particular an organic light-emitting diode (OLED), for example.

The light-emitting component extends in a vertical direction between a first main plane and a second main plane, wherein the vertical direction can run transverse or perpendicular to the first and/or second main plane. The main planes can be the cover surface and the bottom surface of the light-emitting component, for example. The light-emitting component extends in a planar manner in the lateral direction, for example, at least in places parallel to the main planes, and has a thickness in the vertical direction, which is small compared to a maximum extent of the light-emitting component in the lateral direction.

In at least one embodiment according to the first aspect, the layer sequence is configured to generate light during operation of the light-emitting component, in particular in one or multiple active regions. Here, white or colored light can be generated in the layer sequence. In this context, the layer sequence includes organic layers, for example. In particular, the light-emitting component can be an organic light-emitting diode then.

In at least one embodiment according to the first aspect, the light-emitting component includes a first electrode in particular on a side of the layer sequence facing the bottom surface of the light-emitting component as well as a second electrode on a side of the layer sequence facing away from the bottom surface.

At least one of the electrodes can be formed transparent. In particular, the respective electrode can comprise a transparent conductive oxide (TCO) to that end. Transparent conductive oxides are transparent, conductive materials, usually metal oxides such as zinc oxide, tin oxide, cadmium oxide, titanium oxide, indium oxide or indium tin oxide (ITO).

The marking extends particularly in the lateral direction, e.g., parallel to the bottom surface or cover surface of the light-emitting component. Here, the marking is provided and configured in such a way that it can be optically read from outside the light-emitting component. In this context, the marking may include a text, an image and/or a pattern.

In at least one embodiment according to the first aspect, the marking is formed as a luminescence degradation of the layer sequence. Here, it is made use of the fact that luminescent properties of the light-emitting component are influenced by ageing of the light-emitting component. Emission of light during operation of the light-emitting component can be reduced due to the ageing. In this context, luminescence degradation refers to a targeted influencing of the luminous properties of the light-emitting component, in particular in a region of the marking. Here, a degradation of the luminous properties includes an artificial ageing of the layer sequence, for example.

Advantageously, the marking can be arranged in an active region of the light-emitting component, so that a redundant surface for marking the light-emitting component can be dispensed with, for example, thereby contributing to a compact design of the light-emitting component. Furthermore, the marking of the layer sequence contributes to a counterfeit protection as well as traceability of the light-emitting component, as the marking is directly coupled to a functionality of the light-emitting component, so that a deliberate or undeliberate removal of the marking very probably involves an impairment of the functionality up to the destruction of the light-emitting component.

In at least one embodiment according to the first aspect, the marking has a reduced electroluminescence during light-emitting operation of the light-emitting component compared to a region of the layer sequence that is free of the marking. In an advantageous manner, this allows reading the marking of a functional component. In this context, the marking can be perceived to be darker compared to the region that is free of the marking.

In at least one embodiment according to the first aspect, the marking has a reduced photoluminescence when irradiated, in particular when irradiated with ultraviolet radiation, compared to a region of the layer sequence that is free of the marking. In an advantageous manner, this allows reading the marking of a defective component. In this context, the marking can be perceived to be darker compared to the region that is free of the marking.

In at least one embodiment according to the first aspect, the layer sequence includes at least one organic layer. In particular, the light-emitting component can be an organic light-emitting diode then. In particular, the luminescence degradation of the light-emitting component depending on the ageing can be particularly pronounced in a layer sequence having organic layers, contributing to a simple production of the light-emitting component having the marking. For example, the organic layer and/or a further layer of the layer sequence, such as a so-called “interface” between one of the electrodes and the at least one organic layer can have the luminescence degradation.

In at least one embodiment according to the first aspect, the at least one organic layer comprises the marking. Organic layers can, e.g., be particularly sensitive for irradiation, in particular UV radiation, so that the marking can be applied particularly easily during the production of the light-emitting component.

In at least one embodiment according to the first aspect, the layer sequence, in particular the at least one organic layer, is defective or destroyed in a targeted manner in the region of the marking. Depending on an operating state of the light-emitting component as well as an irradiation of the light-emitting component, the layer sequence destroyed in the region of the marking has a significantly reduced luminescence, in particular electroluminescence or photoluminescence in the region of the marking. In particular, the layer sequence destroyed in the region of the marking does not have any electroluminescence or photoluminescence. In this case, this is a physical feature that can unambiguously be proved on the finished light-emitting component with analysis methods of semiconductor technology. The luminescence degradation can unambiguously be discriminated from a marking process which can be produced by means of a material removal, material application or discoloration of at least one layer of the light-emitting component. Thus, the stated feature is in particular not a method feature.

In at least one exemplary embodiment according to the first aspect, the marking is formed to be intrinsic with respect to the light-emitting component, so that an outer surface of the light-emitting component is free from the marking. In particular, the outer surface is a surface of the light-emitting component facing the outside, such as the cover surface, the bottom surface and/or a lateral surface. This advantageously contributes to a high traceability and counterfeit protection of the light-emitting component. Here, the marking is particularly protected against a deliberate or undeliberate removal of the marking, for example, in view of a mechanical removal of the surface facing the outside.

In at least one embodiment according to the first aspect, the marking includes a plurality of degraded regions separated from one another by means non-degraded regions. Here, the degraded regions can be different from one another in shape and/or size. Furthermore, the non-degraded a can be different from one another in shape and/or size. Moreover, the degraded and non-degraded regions can be different from one another in shape and/or size.

For example, the marking has a grid including grid cells, which can in each case be formed to be degraded or non-degraded. In this context, in each case multiple neighboring grid cells can form a degraded or non-degraded region. This advantageously contributes to a particularly simple and precise forming of the marking during the production of the light-emitting component having the marking.

In at least one embodiment according to the first aspect, the marking includes a coding. This contributes to a high information content of the marking.

In at least one variant of the embodiment, the marking includes a binary coding of degraded and non-degraded regions. The coding can be a one-dimensional coding, e.g., a bar code. The coding can also be a two-dimensional coding, such as a data matrix.

In at least one variant, the marking includes a coding of multistage degraded and non-degraded regions. The multistage degraded regions are, for example, regions having a defective layer sequence and regions with destroyed layer sequence, so that different luminescent properties of these regions can be visually perceived. The coding can then be a three-dimensional coding then, for example.

In at least one embodiment according to the first object, a lateral extent of the marking is between 1 μm×1 μm and 10 mm×10 mm. The lateral extent of the marking is between 5 μm×5 μm and 1 mm×1 mm, in particular between 20 μm×20 μm and 500 μm×500 μm. In particular, the lateral extent of the marking is between 50 μm×50 μm and 150 μm×150 μm. In an advantageous manner, a resolution of the marking can be below the resolution limit of the human eye, so that the marking cannot be read by the human eye. In particular, this can contribute to a counterfeit protection of the light-emitting component. In this context, the marking can be completely invisible to the human eye, for example. Furthermore, such a lateral extent of the marking particularly contributes to a high light yield during operation of the light-emitting component.

According to a second aspect, a method for producing the light-emitting component having a marking is provided. The light-emitting component can in particular be the above-described light-emitting component according to the first aspect, which can be produced by means of a following method according to the second aspect, so that all features disclosed for the method are also disclosed for the light-emitting component and vice versa.

In at least one embodiment according to the second aspect, a marking is formed in the layer sequence through luminescence degradation of the layer sequence by means of coherent radiation. A laser can be used to that end, in particular. In this context, the luminescence degradation of the layer sequence can also be referred to as laser degradation. A power emitted in the course of the luminescence degradation is restricted in such a way that a removal of material of the layer sequence, e.g., laser ablation, is prevented here. Furthermore, the power output is limited in such a way that a discoloration of a layer of the light-emitting component is prevented. The marking of the light-emitting component can be invisible depending on an operating state of the light-emitting component as well as an irradiation of the light-emitting component, in particular invisible to the human eye.

A region of the layer sequence degraded by means of coherent radiation can, in particular, be circular or ellipsoid or consist of multiple neighboring and/or overlapping ellipsoid or circular segments. A smallest lateral extent of the degraded region, e.g., a diameter of a circularly degraded region, can be between 1 μm and 10 μm, in particular 5 μm, for example.

In at least one embodiment according to the second aspect, a wavelength of the coherent radiation is between 150 nm and 550 nm. In particular, the wavelength of the coherent radiation is between 250 nm and 470 nm, in particular between 330 nm and 370 nm. The light-emitting component can in particular be sensitive for radiation in this wavelength range. Here, the wavelength may depend on a transmission of the layer sequence and/or a transmission of at least one layer surrounding the layer sequence. In this context, the wavelength can be greater than 200 nm, in particular greater than 330 nm, for example.

In at least one embodiment according to the second aspect, the light-emitting component includes a first electrode. In the lateral direction, the first electrode extends at least partially over the layer sequence. The marking is formed in the layer sequence in the vertical direction from the side of the layer sequence that faces away from the first electrode. After forming the marking, a second electrode is applied on to the layer sequence on the side of the layer sequence facing away from the first electrode in the vertical direction. The second electrode extends at least partially over the layer sequence in the lateral direction.

After this step, the first electrode is therefore arranged on a side of the layer sequence that faces the bottom surface of the light-emitting component. Furthermore, after this step, the second electrode is arranged on a side of the layer sequence facing away from the bottom surface of the light-emitting component. Such an order for forming the marking can, e.g., be chosen if a transmission of the coherent radiation through the second electrode and/or a further layer surrounding the layer sequence in the vertical direction toward the second electrode is too small or prevented. The light-emitting component is a so-called “bottom emitter”, for example.

In at least one embodiment according to the second aspect, the light-emitting component includes an auxiliary layer. The auxiliary layer extends in the lateral direction at least partially over the layer sequence. The marking is formed in the layer sequence in the vertical direction through the auxiliary layer from a side of the layer sequence facing the auxiliary layer. In particular, the auxiliary layer is formed to be transparent to that end. In this case, the auxiliary layer forms the cover surface of the light-emitting component, for example. The light-emitting component is a so-called “top emitter” or a so-called “transparent OLED”, for example.

The auxiliary layer can have a monolayer or multilayer configuration. The auxiliary layer includes a protective layer, for example. The auxiliary layer or a sub-layer thereof can furthermore be formed as a connecting layer for an integral connection, for example. Furthermore, the auxiliary layer or a sub-layer thereof can be formed to be electrically-insulating, for example.

Such an order for forming the marking can, e.g., be selected if a sufficient transmission of the coherent radiation through the second electrode and the auxiliary layer for influencing the luminescent properties of the layer sequence is provided. In particular, this step can be performed on completely finished light-emitting components, e.g., in a separate or final step of the method according to the second aspect.

In at least one embodiment according to the second aspect, the light-emitting component includes a substrate. The substrate extends in the lateral direction at least partially over the layer sequence. The marking is formed in the layer sequence through the substrate in the vertical direction from a side of the layer sequence facing the substrate. In particular, the substrate is formed to be transparent to that end. The substrate forms the bottom surface of the light-emitting component, for example. The light-emitting component is, e.g., a so-called “bottom emitter” or a so called “transparent OLED”. The substrate is, e.g., a glass substrate or a polymer substrate.

Such an order for forming the marking can, for example, be selected if a sufficient transmission of the coherent radiation through the first electrode and the substrate for influencing the luminescent properties of the layer sequence is provided. In particular, this step can be performed on completely finished light-emitting components, e.g., in a separate or final step of the method according to the second aspect.

### BRIEF DESCRIPTION OF THE DRAWINGS

Further features, configurations and expediencies result from the following description of the exemplary embodiments in conjunction with the Figures.

The figures show in:

FIG. 1 is a first exemplary embodiment of a method for producing a light-emitting component having a marking by means of a schematically-illustrated sectional view;

FIG. 2 is the light-emitting component according to FIG. 1 by means of a schematically-illustrated plan view;

FIG. 3 is a second exemplary embodiment of a method for producing the light-emitting component having a marking by means of a schematically-illustrated sectional view; and

FIG. 4 is a third exemplary embodiment of a method for producing the light-emitting component having a marking by means of a schematically-illustrated sectional view.

Like, identical or similar elements are denoted with the same reference characters throughout the figures. The figures and the size ratios of the elements illustrated in the Figures are not to be considered to be true to scale. Rather, individual elements and in particular layer thicknesses can be illustrated in an exaggerated size for the purpose of a better illustration and/or understanding.

### DETAILED DESCRIPTION OF ILLUSTRATIVE EMBODIMENTS

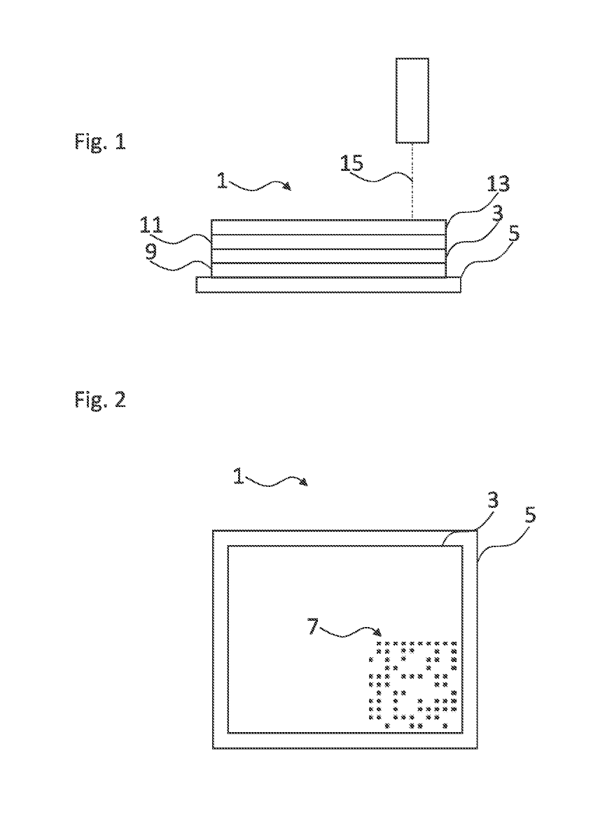

FIG. 1 illustrates a first exemplary embodiment of a method for producing a marked light-emitting component 1 in a schematic sectional view.

A substrate 5 is provided, which extends in the lateral direction. Together with a side, the substrate 5 forms, e.g., a bottom surface of the light-emitting component 1. A layer sequence 3 for the generation of light is arranged on a side of the substrate 5 facing away from the bottom surface of the light-emitting component 1. The light-emitting component 1 includes a first electrode 9 on a side of the layer sequence 3 that faces the substrate 5. The light-emitting component further includes a second electrode 11 on a side of the layer sequence 3 facing away from the substrate 5.

The layer sequence 3 includes organic semiconductor material, in particular organic layers for the emission of light and for supplying charge carriers. In particular, the light-emitting component 1 is an organic light-emitting diode chip having an active region provided for the generation of light (not explicitly shown in the figures for the sake of simplicity).

The electrodes 9, 11 comprise, e.g., a conductive oxide, metal, metal alloy or metal oxide such as aluminum, silver, a silver-magnesium-alloy or indium tin oxide. Here, electrodes 9, 11 form the cathode and anode for the electrical contacting of the light-emitting component 1. In this exemplary embodiment, the substrate 5 is formed as an opaque metal foil to be flexible. An emission direction of the light-emitting component 1 is directed to a side of the layer sequence 3 that faces the second electrode 11 (so-called “top emitter”). In this context, at least the second electrode 11 is formed to be transparent.

In other embodiments, both the substrate 5 and the two electrodes 9, 11 can be of transparent design. In this case, the emission direction of the light-emitting component is, e.g., unobstructed in the vertical direction (so-called “transparent OLED”). To that end, the substrate 5 can be formed of glass, for example.

The light-emitting component 1 further includes a transparent auxiliary layer 13 arranged in the vertical direction on a side of the second electrode 11 facing away from the layer sequence 3. The auxiliary layer 13 forms a cover layer of the light-emitting component 1, for example. The auxiliary layer 13 includes one or multiple sub-layers, for example. Here, the auxiliary layer 13 or a sub-layer thereof if formed as a protective layer of the light-emitting component 1 and includes glass, for example. The auxiliary layer 13 is a final encapsulation of the light-emitting component 1, for example. In particular, the light-emitting component 1 according to the first exemplary embodiment can be provided to be ready for operation.

In the context of the forming of a marking 7 (see FIG. 2) for simplified traceability and improved counter protection of the light-emitting component 1, the light-emitting component 1 is applied with coherent radiation 15 from the cover surface, e.g., in a separate or final step.

To that end, a UV laser can be used, in particular, in order to achieve an artificial ageing of the light-emitting component 1 in a region of the marking 7 (a so-called local degradation). In this case, it is made use of the fact that the light-emitting component 1, in particular the layer sequence 3, is degraded under the impact of ultraviolet (UV) light, i.e., by selective irradiation of the light-emitting component 1 with coherent radiation 15, a region of the light-emitting component 11 can be degraded to such an extent that its luminescent properties are severely impaired (in this context, the irradiation can also be referred to as luminescence degradation). The degraded region may in particular have significantly reduced electroluminescence during light-emitting operation of the light-emitting component 1. Furthermore, the degraded region can have a severely-reduced photo luminescence when irradiated, in particular when irradiated with UV radiation. This advantageously allows reading the marking 7 both in a functional and in a defective light-emitting component 1. In this context, a degraded region of the marking 7 can be perceived to be darker compared to a non-degraded region.

In this case, the marking 7 is formed intrinsically in the light-emitting component 1, so that an outer surface of the light-emitting component 1, including the cover surface, the bottom surface and the side surfaces of the light-emitting component 1, is free of the marking. In particular, the organic semiconductor material comprises the marking 7 after this step, e.g., an emitter layer of the layer sequence 3. Alternatively or in addition however, further layers of the light-emitting component 1 may comprise the marking 7, e.g., e.g., a so-called “interface” between the cathode and the emitter layer.

As illustrated in FIG. 2, the marking 7 comprises multiple degraded regions spaced from one another by non-degraded regions. In this exemplary embodiment, a shape and a size of the degraded regions are formed equally. The degraded regions are illustrated schematically as quadratic. However, the degraded regions may have any shape, in particular a circular shape.

In particular, for forming the marking 7, a laser having a wavelength of 330 nm to 370 nm, particularly 355 nm, is used. A region degraded in such a way is in particular circular. In this case, a diameter of the region degraded in such a way can be merely 5 μm, so that this region is not per se perceivable due to the poor resolution capability of the human eye.

As illustrated in FIG. 2, the degraded regions are arranged in a grid. In particular, the degraded and non-degraded regions of the marking 7 form a two-dimensional binary coding, e.g., a so-called “data matrix” or “dot matrix”. In this exemplary embodiment, the marking 7 includes 11×11 grid cells. A lateral extent of the marking 7 can be 55 μm×55 μm then, for example.

As illustrated in FIG. 2, the individual grid cells are not additionally spaced from one another by non-degraded regions, so that the lateral extent of the marking 7, e.g., doubles, namely is 110 μm×110 μm, for example. The non-degraded regions for spacing the grid cells advantageously allow a higher light yield of the light-emitting component 1 in the region of the marking 7. In particular, the individual degraded regions can be irradiated during operation of the light-emitting component 1, thereby contributing to making the marking 7 invisible to the human eye.

The number of grid cells can be different in other exemplary embodiments. In particular, the number can be between 1 and 1000 grid cells per column and/or line, depending on an information content of the marking 7. Here, the number of grid cells per column can differ from the number of grid cells per line. Furthermore, the grid does not necessarily have to consist of lines or columns arranged perpendicular to one another and other patterns such as a hexagonal arrangement of the grid cells are possible just as well. Here, a lateral extent of the marking 7 is preferably less than 1 mm×1 mm, so that a high light yield of the light-emitting component 1 is made possible.

Furthermore, the marking 7 is not limited to a coding. Rather, simple labels as well as different, one-dimensional, two-dimensional or multi-dimensional codings can be implemented, as mentioned in the general section of the description.

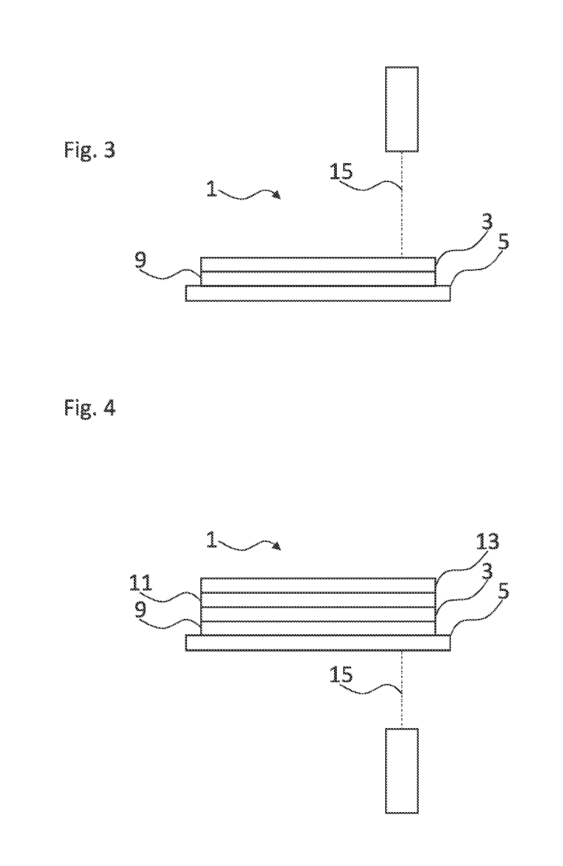

The second exemplary embodiment of a method for producing a light-emitting component 1 having a marking illustrated by means of FIG. 3 is different from the first exemplary embodiment in that the marking 7 is formed in the layer sequence 3 of the light-emitting component 1 in an intermediate step during the production, i.e., in particular in a light-emitting component 1 that is not ready for operation. This can, e.g., be the case, if the light-emitting component 1 is a so-called “bottom emitter”, in which a side of the layer sequence 3 facing away from the substrate 5 is covered by at least one opaque layer. The opaque layer is, e.g., a second electrode 11 formed to be reflective.

In this case, forming of the marking 7 from the cover surface of the light-emitting component 1 by means of coherent radiation 15 is only possible prior to the application of the opaque layer. As illustrated in FIG. 3, the light-emitting component 1 is applied with the coherent radiation after the application of the layer sequence 3.

In contrast, the light-emitting component 1 can also be a so-called “top emitter” or a “transparent OLED”, in which the forming of the marking 7 can be effected any time after application of the layer sequence 3 from the cover surface of the light-emitting component 1.

After forming the marking 7, the other layers of the light-emitting component 1 are applied, for example, analogously to the first exemplary embodiment.

The third exemplary embodiment of a method for producing a marked light-emitting component 1 illustrated by means of FIG. 4 differs from the first exemplary embodiment in that the marking 7 is formed in the layer sequence 3 from the bottom surface of the light-emitting component 1 by means of coherent radiation 15. In this context, the first electrode 9 as well as the substrate 5 are of transparent design. Here, the light-emitting component 1 is a so called “bottom emitter” or a “transparent OLED”. The forming of the marking 7 can be effected any time after application of the layer sequence 3, for example, also analogously to the second exemplary embodiment.

1-16. (canceled)

17. A light-emitting component comprising:
a layer sequence for generating light,
wherein the layer sequence comprises a marking, and
wherein the marking is formed as a luminescence degradation of the layer sequence.

18. The light-emitting component according to claim 17, wherein the layer sequence for generating light is aged in a targeted manner in a region of the marking.

19. The light-emitting component according to claim 17, wherein, when the light-emitting component is in normal operation, the marking has a reduced electroluminescence compared to a region of the layer sequence that is free of the marking.

20. The light-emitting component according to claim 17, wherein the marking has a reduced photoluminescence under UV irradiation compared to a region of the layer sequence that is free of the marking.

21. The light-emitting component according to claim 17, wherein the layer sequence includes at least one organic layer.

22. The light-emitting component according to claim 21, wherein the at least one organic layer comprises the marking.

23. The light-emitting component according to claim 21, wherein the organic layer is defective or destroyed in a targeted manner in a region of the marking.

24. The light-emitting component according to claim 17, wherein the marking is formed intrinsically with respect to the light-emitting component so that an outer surface of the light-emitting component is free of the marking.

25. The light-emitting component according to claim 17, wherein the marking includes a plurality of degraded regions, the degraded regions are separated from one another by non-degraded regions.

26. The light-emitting component according to claim 17, wherein the marking includes a coding.

27. The light-emitting component according to claim 17, wherein a lateral extent of the marking is between 1 μm*1 μm and 150 μm*150 μm.

28. A method for producing a light-emitting component having a layer sequence for generating radiation, the method comprising:
forming a marking by coherent radiation, wherein the marking comprises a luminescence degradation in the layer sequence.

29. The method according to claim 28, wherein a wavelength of the coherent radiation is between 150 nm and 550 nm.

30. The method according to claim 28, further comprising:
forming a first electrode on the layer sequence, wherein the first electrode extends at least partially over the layer sequence in a lateral direction;
forming the marking in the layer sequence in a vertical direction from a side of the layer sequence that faces away from the first electrode; and
after forming the marking in the layer sequence, forming a second electrode on the layer sequence on the side of the layer sequence facing away from the first electrode in the vertical direction so that the second electrode at least partially extends over the layer sequence in the lateral direction.

31. The method according to claim 28, further comprising:
forming an auxiliary layer that at least partially extends over the layer sequence in the lateral direction; and
forming the marking in the layer sequence in a vertical direction through the auxiliary layer from a side of the layer sequence that faces the auxiliary layer.

32. The method according to claim 28, further comprising:
providing a substrate that at least partially extends over the layer sequence in the lateral direction; and
forming the marking in the layer sequence in a vertical direction through the substrate from a side of the layer sequence that faces the substrate.

33. The method according to claim 28, wherein the marking includes a coding, and wherein a lateral extent of the marking is at most 150 μm*150 μm.

34. A light-emitting component comprising:
a layer sequence for generating light,
wherein the layer sequence comprises a marking,
wherein the marking is formed as a luminescence degradation of the layer sequence,
wherein the marking includes a coding, and
wherein a lateral extent of the marking is at most 150 μm*150 μm.
